(19) United States
(12) Patent Application Publication
(10) Pub. No.: US 2009/0218079 A1
(43) Pub. Date: Sep. 3, 2009

(54) HEAT-EMITTING ELEMENT COOLING APPARATUS

(75) Inventors: Michinori Watanabe, Nagano (JP); Haruhisa Maruyama, Nagano (JP); Toshiki Ogawara, Nagano (JP); Koji Ueno, Nagano (JP)

Correspondence Address: RANKIN, HILL & CLARK LLP, 38210 Glenn Avenue, WILLOUGHBY, OH, 44094-7808, US

(73) Assignee: SANYO DENKI CO., LTD., Tokyo (JP)

(21) Appl. No.: 12/393,354

(22) Filed: Feb. 26, 2009

(30) Foreign Application Priority Data
Feb. 29, 2008 (JP) 2008-049538

(51) Int. Cl. H01L 23/46

(52) U.S. Cl. 165/121

(57) ABSTRACT

There is provided a heat-emitting element cooling apparatus capable of enhancing cooling effect on a heat-emitting element as well as reducing noise. A heat sink includes a core portion and a plurality of radiation fins fixed to the core portion. Dimensions of the core portion and the radiation fins are defined in such a manner that the diameter L1 of the core portion should be 37% to 45% of the diameter L2 of a shape depicted by a virtual connecting line which connects end portions of the radiation fins.

### BACKGROUND OF THE INVENTION

The present invention relates to a heat-emitting element cooling apparatus for cooling a heat-emitting element such as an electronic component.

A conventionally known heat-emitting element cooling apparatus includes a heat sink having a core portion and a plurality of radiation fins, and a fan unit. In this apparatus, a heat-emitting element to be cooled is mounted on the rear surface of the core portion, and the radiation fins are fixed to the core portion. The fan unit, which is disposed over the heat sink, blows air along two or more radiation fins to promote heat dissipation from the radiation fins. In this heat-emitting element cooling apparatus, heat generated from the heat-emitting element is transferred from the core portion to the radiation fins. Then, the air flowing from the fan unit along the radiation fins carries away the heat of the radiation fins, thereby cooling the heat-emitting element.

In a heat-emitting element cooling apparatus disclosed in Japanese Patent Application Publication No. 2005-327854 (JP2005-327854A), a core portion of the heat sink has a columnar shape, and a plurality of radiation fins are arranged in such a manner that a virtual connecting line connecting end portions of the plurality of radiation fins forms into or depicts a circle or substantially a circle in shape as viewed from the side where a fan unit is disposed.

In recent years, however, with the higher performance of an electronic component, a larger amount of heat is generated from the heat-emitting element. Accordingly, there have been the demands for further enhancing cooling performance of the heat-emitting element cooling apparatus. To this end, several measures have been taken in which the area of the fin in the heat sink is increased or a member having a high thermal conductivity, such as copper, is inserted into a core portion of the heat sink. In such a conventional technique, however, it has not been taken into consideration how the dimensional relationship between the radiation fins and the core portion should be determined to enhance cooling performance and reduce noise, and the apparatus design has been made with a cut-and-try approach.

### SUMMARY OF THE INVENTION

An object of the present invention is to provide a heat-emitting element cooling apparatus capable of enhancing cooling effect on the heat-emitting element as well as reducing noise.

A heat-emitting element cooling apparatus of which improvements are aimed at in the present invention comprises a heat sink and a fan unit. The heat sink includes a core portion on the rear surface of which a heat-emitting element to be cooled is mounted and a radiation fin structure including a plurality of radiation fins fixed to the core portion. The fan unit is disposed over the heat sink and blows air along the plurality of radiation fins to promote heat dissipation from the radiation fins. In the heat sink used in the present invention, the core portion is constituted by a columnar body formed of a material having a higher thermal conductivity than that of a material employed for forming the radiation fin structure. The core portion is arranged to stand vertically with respect to the fan unit so that the center of the core portion substantially coincides with the center of the fan unit. The radiation fins are arranged in such a manner that a virtual connecting line connecting end portions of the radiation fins depicts or forms into a circle or substantially a circle in shape as viewed from the fan-unit side or the side where the fan unit is disposed. In the present invention, dimensions of the core portion and radiation fins are defined so that the ratio of the diameter of the columnar body constituting the core portion to that of the shape depicted or formed by the virtual connecting line should be 37% to 45%. If the ratio of the diameter of the columnar body to the diameter of the shape depicted by the virtual connecting line is smaller than 37%, the amount of heat transferred to the radiation fins passing through the core portion is reduced, thereby degrading the cooling performance. If the ratio of the diameter of the columnar body to the diameter of the shape depicted by the virtual connecting line is larger than 45%, the entire weight of the heat sink is increased, and the core portion itself acts as a resistance to the wind supplied from the fan unit, thereby degrading cooling performance and radiating effect. If the diameter of the columnar body constituting the core portion is determined to be 37% to 45% of the diameter of the shape depicted by the virtual connecting line, it is possible to enhance the cooling performance more than ever and reduce occurrence of noise.

The radiation fin structure may preferably be constituted by a cylindrical body with which the columnar body constituting the core portion is tightly fitted, and the plurality of radiation fins integrally formed with the cylindrical body. The radiation fins and cylindrical body may preferably be formed integrally with each other. A concaved or recessed portion opened toward the fan unit is formed on the fan-unit side end portion of the columnar body or an end portion of the columnar body that is located on the side of the fan unit. The concaved portion faces a motor portion of the fan unit and is not exposed to the wind generated by the fan unit. Therefore, although the formation of the concaved portion reduces the weight of the core portion, the cooling performance is not significantly affected. If such a core portion is formed, it is possible to arbitrarily change the material of the columnar body according to the usage and reduce the weight of the core portion.

The thermal conductivity of the columnar body is higher than that of the cylindrical body. Thus, it is possible to obtain required cooling performance without increasing the size of the columnar body more than necessary. Further, it is preferable that the end portions of the radiation fins are integrally connected to the cylindrical body and are curved in a convex manner to be raised in one peripheral direction or the same peripheral direction of the core portion and that each of the radiation fins is branched into two in the middle thereof in the peripheral direction as viewed from the fan-unit side. By employing thus configured radiation fins, it is possible to enhance the cooling performance and reduce noise.

According to the present invention, the diameter of the columnar body constituting the core portion is determined to be 37% to 45% of the diameter of a shape depicted by the virtual connecting line, whereby it is possible to enhance the cooling performance more than ever and reduce occurrence of noise.

### BRIEF DESCRIPTION OF THE DRAWINGS

FIG. 1 is a vertical cross-sectional view of a heat-emitting element cooling apparatus of a first embodiment which is applied to an electronic component cooling apparatus.

FIG. 2 is a plan view of a heat sink used in the embodiment of FIG. 1.

FIG. 3 is a plan view of a modification of the heat sink.

### DETAILED DESCRIPTION OF PREFERRED EMBODIMENTS

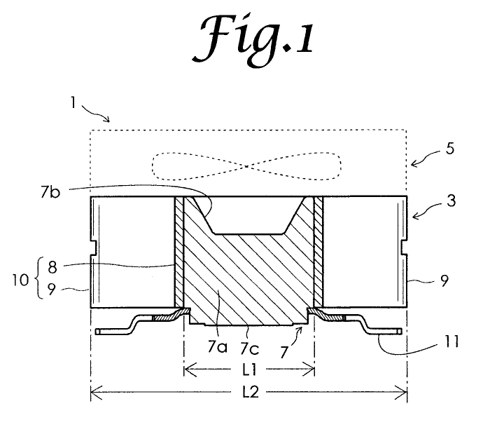

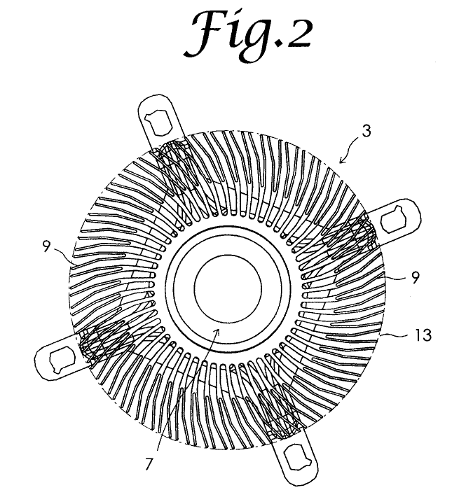

FIG. 1 is a vertical cross-sectional view of a heat-emitting element cooling apparatus 1 of a first embodiment which is applied to an electronic component cooling apparatus. In FIG. 1, an axial-flow fan unit 5 mounted on a heat sink 3 is denoted by a broken line. FIG. 2 is a plan view of the heat sink 3 used in the embodiment shown in FIG. 1. The heat sink 3 includes a core portion 7 and a radiation fin structure 10 fixed to the core portion 7. The radiation fin structure 10 includes a plurality of radiation fins 9. A fixing bracket 11 is fixed to a lower end portion of the core portion 7 of the heat sink 3.

The radiation fin structure 10 is constituted by a cylindrical body 8 with which a columnar body 7a constituting the core portion 7 is tightly fitted, and a plurality of radiation fins 9 integrally formed with the cylindrical body 8. The columnar body 7a constituting the core portion 7 is disposed to be thermally conductive with the cylinder body 8 and is formed of a material having a higher thermal conductivity than that of a material employed for forming the cylindrical body 8. In the present embodiment, the columnar body 7a is formed of a copper having a higher thermal conductivity than the thermal conductivity of the material (aluminum) of the radiation fins 9 and the cylindrical body 8. A concaved or recessed portion 7b is formed in an upper end portion of the columnar body 7a that is located on the side of the axial-flow fan unit 5. The concaved portion 7b faces a motor portion of the axial-flow fan unit 5 and is not exposed to the wind generated by the axial-flow fan unit 5. Therefore, although the formation of the concaved portion 7b reduces the weight of the core portion 7, the cooling performance is not significantly affected. A small diameter portion 7c whose diameter is reduced to allow fitting of the fixing bracket 11 is formed at a lower end portion of the columnar body 7a. A heat-emitting element to be cooled, such as a CPU, is mounted on an end surface of the small diameter portion 7c in a heat conductive manner or in such a manner that heat conduction may be achieved.

The radiation fins 9 are arranged in such a manner that a virtual connecting line 13 connecting end portions of the radiation fins 9 depicts or forms into substantially a circle in shape as viewed from the side of the fan unit 5 or the fan-unit side. Further, the end portions of the radiation fins 9 are integrally connected to the cylindrical body 8 and are curved in a convex manner to be raised in one peripheral direction or the same peripheral direction of the core portion 7. Further, each of the radiation fins 9 is branched into two in the middle thereof in the peripheral direction as viewed from the fan-unit 5 side. By employing thus configured radiation fins 9, it is possible to enhance the cooling performance of the heat-emitting element apparatus and reduce noise.

In the present embodiment, dimensions of the core portion 7 and the radiation fins 9 are defined so that the ratio of the diameter L1 of the columnar body 7a constituting the core portion 7 to the diameter L2 of a shape depicted by the virtual connecting line 13 should be 37% to 45%. If the ratio of the diameter L1 to the diameter L2 is smaller than 37%, the amount of heat transferred to the radiation fins 9 passing through the core portion 7 is reduced, thereby degrading the cooling performance. If the ratio of the diameter L1 to the diameter L2 is larger than 45%, the entire weight of the heat sink 3 is increased, and the core portion 7 itself acts as a resistance to the wind supplied from the fan unit 5, thereby degrading cooling performance and radiating effect. If the diameter of the core portion is determined to be 37% to 45% of the diameter of the virtual connecting line, it is possible to enhance the cooling effect more than ever and reduce occurrence of noise.

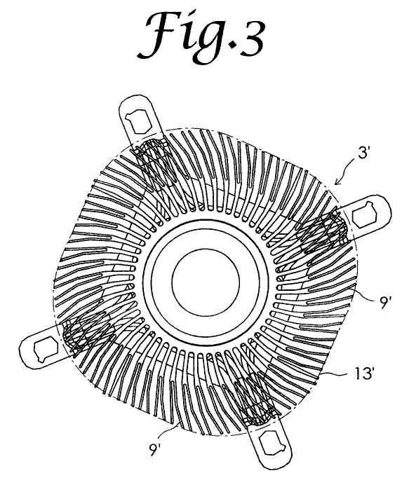

In the above embodiment, the virtual connecting line 13 connecting the end portions of the plurality of radiation fins 9 depicts or forms into substantially a circle in shape as viewed from the fan-unit side where the fan unit 5 is disposed. Alternatively, as with a heat sink 3′ shown in FIG. 3, a virtual connecting line 13′ connecting end portions of a plurality of radiation fins 9′ may depict or form into a nearly circle in shape as viewed from the fan-unit 5 side. In the heat sink of FIG. 3, the virtual connecting line 13′ depicts or forms into a shape as obtained by partially cutting the circular shape at a 90° pitch in the peripheral direction.

In the above-mentioned embodiment, 50 or more radiation fins are arranged outside the core portion 7. The number of the radiation fins to be arranged may appropriately be determined depending on the required level of the cooling performance.

Likewise, although the fixing bracket 11 is fixed to the core portion 7 in the above-mentioned embodiment, it may be fixed to the fan unit 5 or the radiation fins 9.

Further, although the core portion 7 and the cylindrical body 8 are separately formed in the above-mentioned embodiment, the outer periphery of the core portion may be formed using only a columnar body without use of the cylindrical body 8. In this configuration, it is preferable that the core portion and the radiation fins are integrally formed using the same material.

While certain features of the invention have been described with reference to example embodiments, the description is not intended to be construed in a limiting sense. Various modifications of the example embodiments, as well as other embodiments of the invention, which are apparent to persons skilled in the art to which the invention pertains are deemed to lie within the spirit and scope of the invention.

What is claimed is:

1. A heat-emitting element cooling apparatus comprising a heat sink and a fan unit,
the heat sink including a core portion on the rear surface of which a heat-emitting element to be cooled is mounted and a radiation fin structure including a plurality of radiation fins fixed to the core portion;
the core portion of the heat sink being constituted by a columnar body formed of a material having a higher thermal conductivity than that of a material employed for forming the radiation fin structure;
the radiation fins being arranged in such a manner that a virtual connecting line connecting end portions of the radiation fins depicts a circle or substantially a circle in shape as viewed from a fan-unit side where the fan unit is disposed;
the fan unit being disposed over the heat sink and blowing air along the plurality of radiation fins to promote heat dissipation from the radiation fins, wherein dimensions of the core portion and radiation fins are defined so that the ratio of the diameter of the columnar body to the diameter of the shape depicted by the virtual connecting line should be 37% to 45%.

2. The heat-emitting element cooling apparatus according to claim 1, wherein
the heat radiation fin structure is constituted by a cylindrical body with which the columnar body constituting the core portion is tightly fitted, and the plurality of radiation fins integrally formed with the cylindrical body, and
a concaved portion opened toward the fan unit is formed in an end portion of the columnar body that is located on the fan-unit side.

3. The heat-emitting element cooling apparatus according to claim 1, wherein
the end portions of the radiation fins are integrally connected to the cylindrical body and are curved in a convex manner to be raised in the same peripheral direction of the core portion, and
each of the radiation fins is branched into two in the middle thereof in the peripheral direction as viewed from the fan-unit side.
